(19) United States
(12) Patent Application Publication
(10) Pub. No.: US 2023/0343710 A1
(43) Pub. Date: Oct. 26, 2023

(54) SEMICONDUCTOR MEMORY DEVICE

(71) Applicant: SK hynix Inc., Icheon-si (KR)

(72) Inventors: Jae Ho KIM, Icheon-si Gyeonggi-do (KR); Jae Taek KIM, Icheon-si Gyeonggi-do (KR); Han Na GOH, Icheon-si Gyeonggi-do (KR)

(73) Assignee: SK hynix Inc., Icheon-si Gyeonggi-do (KR)

(21) Appl. No.: 17/962,667

(22) Filed: Oct. 10, 2022

(30) Foreign Application Priority Data
Apr. 21, 2022 (KR) 10-2022-0049265

(51) Int. Cl. H01L 23/535; H01L 23/00; H01L 27/11582; H01L 27/11573

(52) U.S. Cl. CPC H01L 23/535; H01L 23/562; H01L 27/11582; H01L 27/11573

(57) ABSTRACT

The present disclosure relates to a semiconductor memory device including a second lower insulating layer, a dummy stack on the second lower insulating layer, a source structure arranged at a same height as the second lower insulating layer, a cell stack on the source structure, a plurality of contact plugs passing through the dummy stack, and a dummy contact passing through a portion of the dummy stack and arranged between the contact plugs.

### CROSS-REFERENCE TO RELATED APPLICATION

The present application claims priority under 35 U.S.C. § 119(a) to Korean patent application number 10-2022-0049265 filed on Apr. 21, 2022, in the Korean Intellectual Property Office, the entire disclosure of which is incorporated by reference herein.

### BACKGROUND

### 1. Technical Field

Various embodiments relate generally to a semiconductor memory device, and more particularly, to a three-dimensional semiconductor memory device.

### 2. Related Art

Non-volatile memory devices retain stored data regardless of power on/off conditions. The increase in integration density of two-dimensional non-volatile memory devices in which memory cells are formed in a single layer over a substrate has recently been limited. Thus, three-dimensional non-volatile memory devices have been proposed in which memory cells are stacked in a vertical direction over a substrate.

A three-dimensional non-volatile memory device may include insulating layers and gate electrodes stacked alternately with each other and channel layers passing therethrough. Memory cells may be stacked along the channel layers. Various structures and manufacturing methods have been developed to improve the operational reliability of three-dimensional non-volatile memory devices.

### SUMMARY

According to an embodiment, a semiconductor memory device may include a second lower insulating layer, a dummy stack on the second lower insulating layer, a source structure arranged at a same height as the second lower insulating layer, a cell stack on the source structure, a plurality of contact plugs passing through the dummy stack, and a dummy contact passing through a portion of the dummy stack and arranged between the contact plugs, wherein each of the dummy and cell stack structures includes a plurality of first material layers separated from each other and stacked on top of each other, wherein the dummy stack further includes a plurality of second material layers arranged alternately with the plurality of first material layers on the second lower insulating layer, and wherein the cell stack further includes a plurality of third material layers arranged alternately with the plurality of first material layers on the source structure.

### BRIEF DESCRIPTION OF THE DRAWINGS

FIG. 1 is a block diagram illustrating a semiconductor device according to an embodiment of the present disclosure;

FIG. 2 is a plan view illustrating a memory block according to an embodiment of the present disclosure;

FIG. 3 is a cross-sectional diagram illustrating a semiconductor memory device taken along line A-A′ and line B-B′ of FIG. 2;

FIG. 4 is a cross-sectional diagram of a cell plug shown in FIG. 3;

FIGS. 5A and 5B are flowcharts illustrating a method of manufacturing a semiconductor memory device according to embodiments of the present disclosure;

FIGS. 6A and 6B are diagrams illustrating processes of providing a lower structure according to embodiments of the present disclosure;

FIGS. 7A, 7B, 7C, 7D, 7E, 7F, 7G, 7H, 7I, and 7J are cross-sectional diagrams taken along line A-A′ and line B-B′ of FIG. 2 for illustrating processes of forming a memory block of a semiconductor memory device;

FIG. 8 is a block diagram illustrating the configuration of a memory system according to an embodiment of the present disclosure; and

FIG. 9 is a block diagram illustrating the configuration of a computing system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

It will be understood that although the terms first and second may be used herein to describe various elements, these elements should not be limited by these terms. The above terms are used only to distinguish one element from another. For example, a first component may be referred to as a second component without departing from the scope of rights of the present disclosure, and likewise a second component may be referred to as a first component. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments are directed to a semiconductor memory device capable of improving operational reliability.

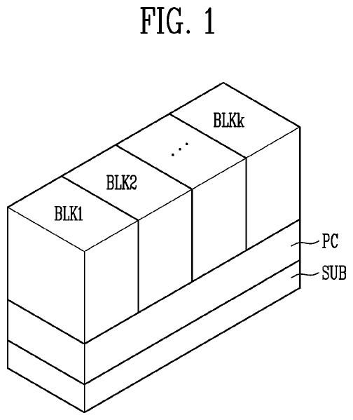

FIG. 1 is a block diagram illustrating a semiconductor device according to an embodiment of the present disclosure.

Referring to FIG. 1, a semiconductor device may include a peripheral circuit structure PC and memory blocks BLK1 to BLKk which are arranged over a substrate SUB. The memory blocks BLK1 to BLKk may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by a selective epitaxial growth method.

The peripheral circuit structure PC may include a row decoder, a column decoder, a page buffer, and a control circuit which constitute a circuit for controlling operations of the memory blocks BLK1 to BLKk. For example, the peripheral circuit structure PC may include an NMOS transistor, a PMOS transistor, a resistor, and a capacitor which are electrically coupled to the memory blocks BLK1 to BLKk. The peripheral circuit structure PC may be arranged between the substrate SUB and the memory blocks BLK1 to BLKk.

Each of the memory blocks BLK1 to BLKk may include a source structure, bit lines, cell strings electrically coupled to the source structure and the bit lines, word lines electrically coupled to the cell strings, and select lines electrically coupled to the cell strings. Each of the cell strings may include memory cells and select transistors which are coupled in series with each other by a channel structure. Each of the select lines may serve as a gate electrode of a corresponding one of the select transistors. Each of the word lines may serve as a gate electrode of a corresponding one of the memory cells.

According to another embodiment, the substrate SUB, the peripheral circuit structure PC, and the memory blocks BLK1 to BLKk may be stacked in reverse order to the order shown in FIG. 1. In this embodiment, the peripheral circuit structure PC may be arranged on the memory blocks BLK1 to BLKk.

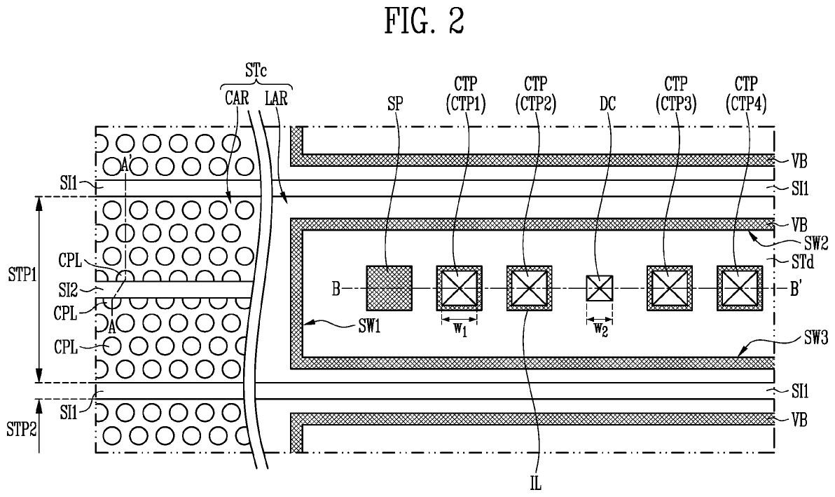

FIG. 2 is a plan view illustrating a memory block according to an embodiment of the present disclosure.

Referring to FIG. 2, at least one of the stack patterns STP1 and STP2 which are separated from each other by first slits SI1 may form a memory block. According to an embodiment, the first and second stack patterns STP1 and STP2 as shown in FIG. 2 may constitute the first and second memory blocks BLK1 and BLK2, respectively. In another embodiment, the first and second stack patterns STP1 and STP2 may constitute one memory block. However, embodiments of the present disclosure are not limited thereto.

Each of the first and second stack patterns STP1 and STP2 may include a dummy stack STd, a cell stack STc, and a vertical barrier VB. The vertical barrier VB may extend along a boundary between the cell stack STc and the dummy stack STd.

The cell stack STc may include a cell array region CAR and a connection region LAR. Cell strings may be arranged in the cell array region CAR. The connection region LAR may extend from the cell array region CAR to surround the dummy stack STd. The dummy stack STd may include a first sidewall SW1 which faces the cell array region CAR and second and third sidewalls SW2 and SW3 which extend from the first sidewall SW1 and face each other. The connection region LAR of the cell stack STc may face the first sidewall SW1, the second sidewall SW2, and the third sidewall SW3 of the cell stack STc, and may extend in line with the first slits SI1.

The cell array region CAR of the cell stack STc may be penetrated by cell plugs CPL. Each of the cell plugs CPL may constitute a cell string corresponding thereto. The cell plugs CPL may be arranged in a matrix format between neighboring first slits SU, or in a zigzag pattern. In the cell array region CAR of the cell stack STc, a top end of the cell stack STc may be penetrated by a second slit SI2. The second slit SI2 may be arranged between the first slits SI1 adjacent to each other.

The dummy stack STd may include a support pillar SP, contact plugs CTP, and a dummy contact DC. The dummy stack STd may be penetrated by the support pillar SP and the contact plugs CTP. The support pillar SP, the contact plugs CTP, and the dummy contact DC may be arranged in a direction in which the dummy stack STd and the vertical barrier VB extend. The dummy contact DC may be arranged between the contact plugs CTP. According to an embodiment, the support pillar SP, the contact plugs CTP, and the dummy contact DC may be arranged at a regular space. However, embodiments of the present disclosure are not limited thereto.

The contact plugs CTP may be surrounded by an insulating layer IL. In another embodiment, the insulating layer IL might not remain around the contact plug CTP, and the contact plug CTP may contact the dummy stack STd.

The contact plugs CTP may be coupled to the peripheral circuit structure PC as shown in FIG. 1. The contact plugs CTP may be arranged in line with the arrangement of the peripheral circuit structure PC. According to an embodiment, the contact plugs CTP may include a first contact plug CTP1, a second contact plug CTP2, a third contact plug CTP3, and a fourth contact plug CTP4. The second contact plug CTP2 and the third contact plug CTP3 may be arranged between the first contact plug CTP1 and the fourth contact plug CTP4. The second contact plug CTP2 may be arranged between the first contact plug CTP1 and the third contact plug CTP3.

A distance between the first contact plug CTP1 and the second contact plug CTP2 may be substantially the same as a distance between the third contact plug CTP3 and the fourth contact plug CTP4. A distance between the second contact plug CTP2 and the third contact plug CTP3 may be greater than the distance between the first contact plug CTP1 and the second contact plug CTP2. However, when contact plugs are locally distributed apart from each other as in the arrangement of the first, second, third, and fourth contact plugs CTP1, CTP2, CTP3, and CTP4, some of the contact plug holes for the contact plugs may be formed to be shorter than an etch target. According to an embodiment, contact plug holes for the second contact plug CTP2 and the third contact plug CTP3 which are spaced apart from each other by a relatively large distance may be formed to be shorter than an etch target. To prevent or mitigate this, the dummy contact DC may be arranged between the second contact plug CTP2 and the third contact plug CTP3.

According to an embodiment, a portion of the dummy stack STd may be penetrated by the dummy contact DC. In other words, the dummy contact DC may have a smaller length than the contact plugs CTP and be disposed in the dummy stack STd.(h1>h2) A top width of each of the contact plugs CTP may be greater than that of the dummy contact DC.(w1>w2)

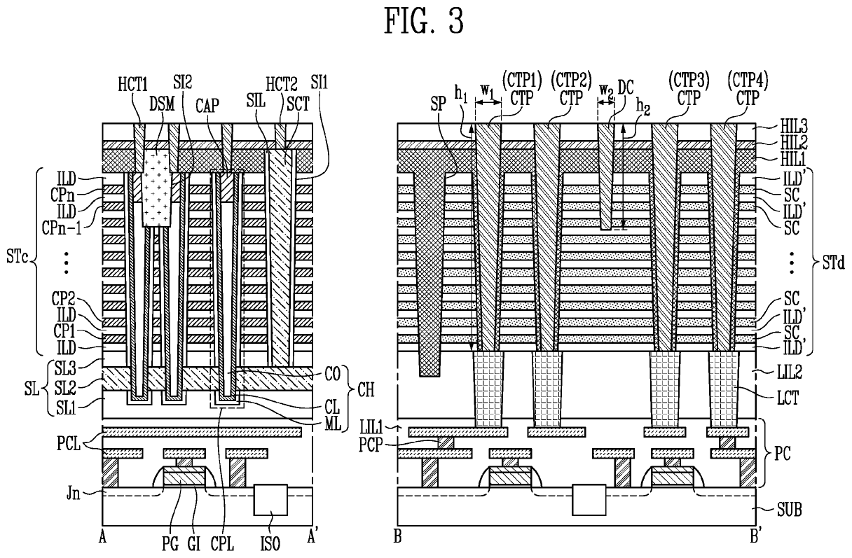

FIG. 3 is a cross-sectional diagram of a semiconductor memory device taken along line A-A′ and line B-B′ of FIG. 2.

Referring to FIG. 3, the cell stack STc may overlap a source structure SL and the peripheral circuit structure PC. The source structure SL may be arranged between the cell stack STc and the peripheral circuit structure PC.

The peripheral circuit structure PC may be arranged on the substrate SUB as described above with reference to FIG. 1. The substrate SUB may include well regions doped with n type or p type impurities. Each of the well regions of the substrate SUB may include active regions which are divided by an isolation layer ISO. The isolation layer ISO may include an insulating material.

The peripheral circuit structure PC may include peripheral gate electrodes PG, a gate insulating layer GI, junctions in, peripheral circuit lines PCL, and lower contact plugs PCP. The peripheral circuit structure PC may be covered by a first lower insulating layer LIL1.

The peripheral gate electrodes PG may serve as gate electrodes of the NMOS transistor and the PMOS transistor. The gate insulating layer GI may be arranged between each of the peripheral gate electrodes PG and the substrate SUB. The junctions in may be defined by injecting n type or p type impurities into the active regions which overlap the peripheral gate electrodes PG. The junctions in may be disposed at both sides of each of the peripheral gate electrodes PG. One of the junctions Jn disposed at both sides of the peripheral gate electrodes PG may serve as a source junction, and the other may serve as a drain junction. The peripheral circuit lines PCL may be electrically coupled to a circuit for controlling a memory block through the lower contact plugs PCP. The circuit for controlling the memory block may include an NMOS transistor, a PMOS transistor, a resistor, and a capacitor as described above with reference to FIG. For example, the NMOS transistor may be coupled to the peripheral circuit lines PCL through the lower contact plugs PCP.

The first lower insulating layer LIL1 may cover the peripheral circuit lines PCL and the lower contact plugs PCP. The first lower insulating layer LIL1 may include a plurality of insulating layers which are stacked on top of each other.

The source structure SL may include first, second, and third source layers SL1, SL2, and SL3. Each of the first and third source layers SL1 and SL3 may extend and overlap the cell stack STc. The second source layer SL2 may be disposed between the first source layer SL1 and the cell stack STc. However, the third source layer SL3 might not be formed in some cases. The cell plug CPL may pass through the cell stack STc and extend into the source structure SL. The source structure SL may surround a lower part of the cell plug CPL.

Each of the first source layer SL1 and the second source layer SL2 may include a doped semiconductor layer. The doped semiconductor layer may include a source dopant. For example, the source dopant may be n type impurities. The third source layer SL3 may include at least one of a doped semiconductor layer and an undoped semiconductor layer. The source structure SL may be coupled to a source contact structure SCT. According to an embodiment, the third source layer SL3 may be penetrated by the source contact structure SCT. The source contact structure SCT may extend from the second source layer SL2 or the first source layer SL1.

The source contact structure SCT may be a conductive material which is disposed in the first slits SI1 of FIG. 2. The source contact structure SCT may include various conductive materials such as a doped silicon layer, a metal layer, a metal silicide layer, and a barrier layer. For example, the source contact structure SCT may include two or more types of conductive materials. For example, the source contact structure SCT may have a stacked structure which includes a doped silicon layer contacting the source structure SL and a metal layer formed on the doped silicon layer. The doped silicon layer may include an n type dopant. The metal layer may include a low-resistance metal, such as tungsten, to reduce resistance.

The source contact structure SCT may be insulated from each of the nth conductive patterns CPn of the cell stack STc by a spacer insulating layer SIL.

The dummy stack STd may overlap a second lower insulating layer LIL2 and the peripheral circuit structure PC. The second lower insulating layer LIL2 may be disposed between the dummy stack STd and the peripheral circuit structure PC. The second lower insulating layer LIL2 may be located at substantially the same height as the source structure SL. In an embodiment, for example, the second lower insulating layer LIL2 may be located at substantially the same level as the source structure SL as shown in FIG. 3.

The second lower insulating layer LIL2 may include lower contacts LCT. Each of the contact plugs CTP may be electrically coupled to the peripheral circuit structure PC by each of the lower contacts LCT.

The dummy stack STd may include dummy insulating layers ILD′ and sacrificial insulating layers SC which are stacked alternately with each other. The cell stack STc may include interlayer insulating layers ILD and conductive patterns CP1 to CPn which are stacked alternately with each other. The cell stack STc may be located at substantially the same height as the dummy stack STd. The interlayer insulating layers ILD may be located at substantially the same height as the dummy insulating layers ILD′. The conductive patterns CP1 to CPn may be located at substantially the same height as the sacrificial insulating layers SC.

The interlayer insulating layers ILD and the dummy insulating layers ILD′ may include the same material and be formed by the same processes. The sacrificial insulating layers SC may include a material having a different etch rate from the interlayer insulating layers ILD and the dummy insulating layers ILD′. For example, the interlayer insulating layers ILD and the dummy insulating layers ILD′ may include silicon oxide, and the sacrificial insulating layers SC may include silicon nitride.

Each of the conductive patterns CP1 to CPn may include various conductive materials such as a doped silicon layer, a metal layer, a metal silicide layer, and a barrier layer. For example, the conductive patterns CP1 to CPn may include two or more types of conductive materials. For example, each of the conductive patterns CP1 to CPn may include tungsten and a titanium nitride (TiN) layer which surrounds the surface of tungsten. Tungsten is a low-resistance metal and may reduce the resistance of the conductive patterns CP1 to CPn. The titanium nitride (TiN) layer may be a barrier layer for preventing a direct contact between tungsten and the interlayer insulating layers RD.

The conductive patterns CP1 to CPn may serve as gate electrodes of a cell string. The gate electrodes of the cell string may include source select lines, word lines, and drain select lines. The source select lines may serve as gate electrodes of source select transistors. The drain select lines may serve as gate electrodes of drain select transistors. The word lines may serve as gate electrodes of memory cells.

For example, the first conductive pattern CP1 which is the closet to the source structure SL, among the conductive patterns CP1 to CPn, may serve as a source select line. The nth conductive pattern CPn which is the farthest away from the source structure SL, among the conductive patterns CP1 to CPn, may serve as a drain select line. However, embodiments of the present disclosure are not limited thereto. For example, one or more conductive patterns which are sequentially stacked adjacent to the first conductive pattern CP1, among the second to (n−1)th conductive patterns CP2 to CPn−1 between the first conductive pattern CP1 and the nth conductive pattern CPn, may serve as different source select lines. In addition, one or more conductive patterns which are sequentially stacked adjacent to the nth conductive pattern CPn, among the second to (n−1)th conductive patterns CP2 to CPn−1, may serve as different drain select lines.

The drain select lines of the cell stack STc may be separated from each other by the second slit SI2. A drain select line isolation structure DSM may be arranged in the second slit SI2. According to an embodiment, the second slit SI2 and the drain select line isolation structure DSM may separate conductive patterns (e.g., CPn and CPn−1), which serve as drain select lines. Into a first group of drain select lines and a second group of drain select lines. Therefore, the first group of the drain select lines and the second group of the drain select lines may be controlled independently of each other.

Conductive patterns which are arranged between the source select lines and the drain select lines, among the conductive patterns CP1 to CPn, may serve as word lines.

The contact plug CTP may pass through the dummy stack STd. In addition, the contact plug CTP may extend to pass through the second lower insulating layer LIL2. The contact plug CTP may be coupled to one of the peripheral circuit lines PCL through the lower contact LCT. For example, the contact plug CTP may be coupled to the peripheral circuit line PCL which is electrically coupled to an NMOS transistor which forms a block select transistor. However, embodiments of the present disclosure are not limited thereto. For example, the contact plug CTP may contact a peripheral circuit line which is coupled to a resistor, a peripheral circuit line which is coupled to a PMOS transistor, or a peripheral circuit line which is coupled to a capacitor.

The cell plugs CPL may pass through the cell stack STc, the third source layer SL3, and the second source layer SL2, and may extend into the first source layer SL1. The cell plugs CPL may pass through the interlayer insulating layers ILD and the conductive patterns CPn of the cell stack STc. A lowermost portion of the cell plug CPL may be arranged in the first source layer SL1. The cell plug CPL may be electrically coupled to the second source layer SL2 of the source structure SL.

Each of the cell plugs CPL may include a channel structure CH and a memory layer ML which surrounds the channel structure CH. The channel structure CH may include a channel layer CL, a core pillar CO, and a capping pattern CAP. The channel layer CL may extend along a sidewall of the memory layer ML. The core pillar CO and the capping pattern CAP may fill a central region of the cell plug CPL. The capping pattern CAP may be arranged on the core pillar CO. The channel layer CL may contact the second source layer SL2. The channel layer CL may be electrically coupled to the second source layer SL2.

The capping pattern CAP of a cell plug which is adjacent to the second slit SI2, among the cell plugs CPL, may be penetrated by the drain select line isolation structure DSM. The depth of the second slit SI2 and the drain select line isolation structure DSM may be controlled so as not to penetrate the cell stack STc.

First to third upper insulating layers HIL1 to HIL3 may be stacked on top of the dummy stack STd and the cell stack STc. The first to third upper insulating layers HIL1 to HIL3 may include a material which is selected in consideration of processes of forming a first upper contact HCT1, a second upper contact HCT2, the contact plug CTP, and the dummy contact DC which pass through the first to third upper layers HIL1 to HIL3. According to an embodiment, the second upper insulating layer HIL2 may be arranged between the first upper insulating layer HIL1 and the third upper insulating layer HIL3, and the second upper insulating layer HIL2 may include a material having a different etch rate from the first and third upper insulating layers HIL1 and HIL3. The second upper insulating layer HIL2 may serve as an etch stop layer during etch processes for forming holes having different depths for the first upper contact HCT2, the second upper contact HCT2, the contact plug CTP, and the dummy contact DC. However, embodiments of the present disclosure are not limited thereto. For example, the first to third upper insulating layers HIL1 to HIL3 may be configured as a single layer.

The support pillar SP may pass through the dummy stack STd and a portion of the second lower insulating layer LIL2. The support pillar SP may include an insulating layer. According to an embodiment, the support pillar SP may include oxide. The support pillar SP and the first upper insulating layer HIL1 may be formed at the same time. The support pillar SP and the first upper insulating layer HIL1 may include the same material.

The dummy contact DC may pass through a portion of the dummy stack STd. The dummy contact DC may be arranged next to the support pillar SP and the contact plugs CTP. The dummy contact DC may be arranged between the plurality of contact plugs CTP. According to an embodiment, the support pillar SP, the contact plugs CTP, and the dummy contact DC may be arranged at the same space. However, embodiments of the present disclosure are not limited thereto.

A top critical dimension of the dummy contact DC may be smaller than that of each of the contact plugs CTP. In other words, a width of a top surface of the dummy contact DC may be smaller than that of a top surface of each of the contact plugs CTP, respectively. (w1>w2) When the holes for the dummy contact DC and the contact plugs CTP are formed at the same time using the same etch process, a depth of the hole for the dummy contact DC may be smaller than that of the hole for the contact plug CTP. Therefore, the height of the dummy contact DC may be smaller than that of the contact plug CTP. (h1>h2) The dummy contact DC and the contact plugs CTP may include the same conductive material.

The cell plugs CPL may be coupled to the first upper contacts HCT1, respectively. The source contact structure SCT may be coupled to the second upper contact HCT2. The first upper contacts HCT1 and the second upper contact HCT2 may pass through at least one of the first to third upper insulating layers HIL1 to HIL3. Though not shown in FIG. 3, each of the first upper contacts HCT1 may contact a bit line corresponding thereto. The second upper contact HCT2 may contact a first upper line for transferring a source signal. Each of the contact plugs CTP may contact a second upper line corresponding thereto. The second upper line may be provided for transferring an operating signal from the peripheral circuit structure PC shown in FIG. 1 to the memory cell array, or for transferring a signal, which is output from the memory cell array, to the peripheral circuit structure PC. According to an embodiment, each of the second upper lines may be for electrically coupling one of the conductive patterns CP1 to CPn corresponding thereto to one of the contact plugs CTP corresponding thereto.

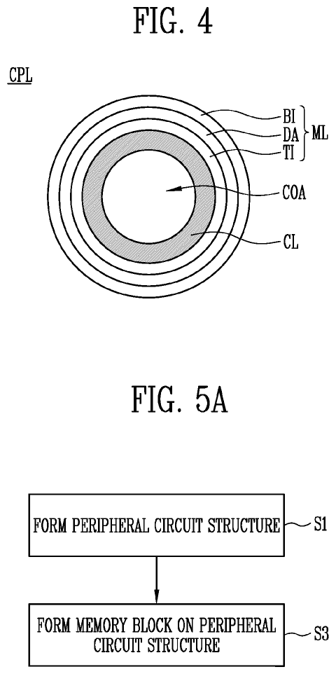

FIG. 4 is a cross-sectional diagram of the cell plug CPL shown in FIG. 3.

Referring to FIG. 4, the channel layer CL of the cell plug CPL may have an annular shape which defines a core region COA. The channel layer CL may be a material layer which is provided as a channel region of a cell string, and may include a semiconductor layer. The core region COA may be filled with the core pillar CO as shown in FIG. 3. The memory layer ML of the cell plug CPL may include a tunnel isolation layer TI, a data storage layer DA, and a blocking insulating layer BI which are sequentially stacked on the surface of the channel layer CL.

The data storage layer DA may include a material layer which stores data being changed, using Fowler-Nordheim tunneling. The data storage layer DA may include various materials, for example, a nitride layer enabling to trap charges. However, the embodiments are not limited thereto. The data storage layer DA may include silicon, a phase change material, or nanodots. The blocking insulating layer BI as shown in FIG. 4 may include an oxide layer which blocks charges. The tunnel isolation layer TI as shown in FIG. 4 may include a silicon oxide layer which enables charge tunneling.

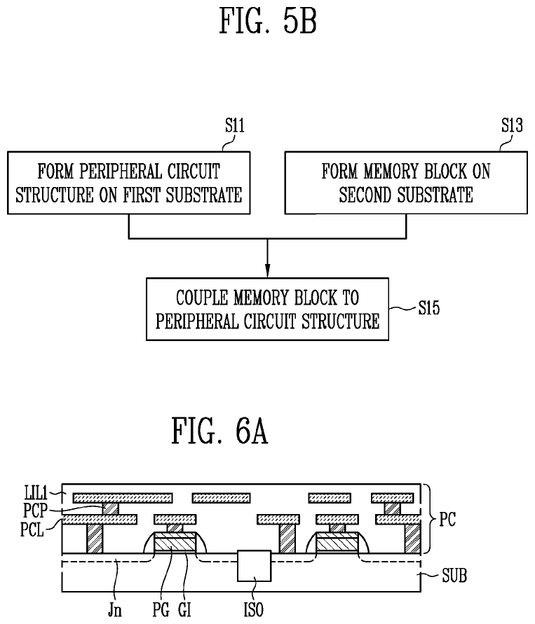

FIGS. 5A and 5B are flowcharts illustrating a method of manufacturing a semiconductor memory device according to embodiments of the present disclosure.

Referring to FIG. 5A, a method of manufacturing a semiconductor memory device according to an embodiment may include step S1 at which a peripheral circuit structure is formed on a substrate and step S3 at which a memory block is formed on the peripheral circuit structure.

The substrate which is provided at step S1 may be the substrate SUB as described above with reference to FIG. 3. The peripheral circuit substrate which is formed at step S1, may be the peripheral circuit structure PC as described above with reference to FIG. 3.

The memory block which is formed at step S3 may include the source structure SL, the cell stack STc, and the dummy stack STd as described above with reference to FIG. 3.

Referring to FIG. 5B, a method of manufacturing semiconductor memory device according to an embodiment of the present disclosure may include step S11 at which a peripheral circuit structure is formed on a first substrate, step S13 at which a memory block is formed on a second substrate, and step S15 at which the peripheral circuit structure is coupled to the memory block.

The first substrate which is provided at step S11 may be the substrate SUB as described above with reference to FIG. 3. The peripheral circuit substrate which is formed at step S11 may be the peripheral circuit structure PC as described above with reference to FIG. 3.

The memory block which is formed at step S13 may include the source structure SL, the cell stack STc, and the dummy stack STd as described above with reference to FIG. 3.

Step S15 may refer to a process by which the peripheral circuit structure formed at step S11 and the memory block formed at step S13 are coupled to each other. According to an embodiment of the present disclosure, step S15 may be carried out so that pad portions included in the peripheral circuit structure and pad portions included in the memory block may be bonded to each other.

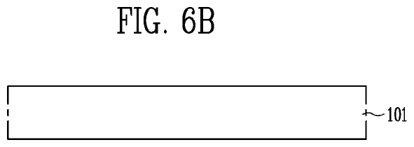

FIGS. 6A and 6B are diagrams illustrating processes of providing a lower structure according to embodiments of the present disclosure.

According to an embodiment of FIG. 6A, a lower structure may be the substrate SUB on which the peripheral circuit structure PC is formed through step ST1 of FIG. 5A. However, a description of the isolation layer ISO, the junction 3n, the gate insulating layer GI, the peripheral gate electrode PG, the peripheral circuit line PCL, and the lower contact plug PCP of the substrate SUB will be omitted since they are the same as described above with reference to FIG. 3.

According to the embodiment as shown in FIG. 6B, the lower structure may be a second substrate 101 which is provided at step ST13 as shown in FIG. 5B.

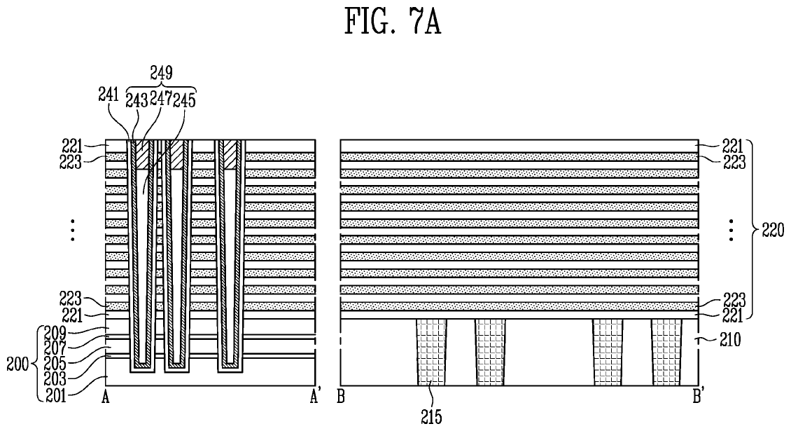

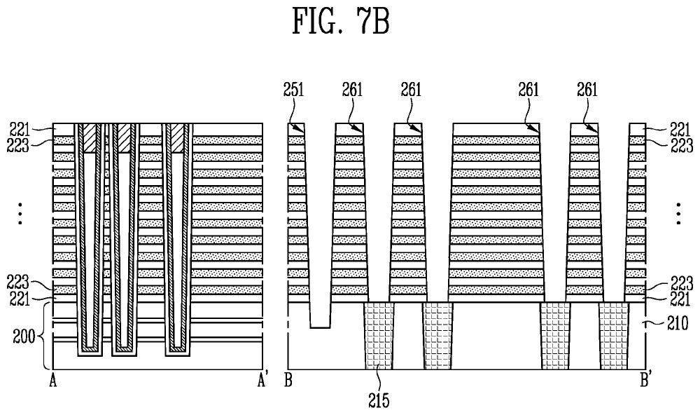

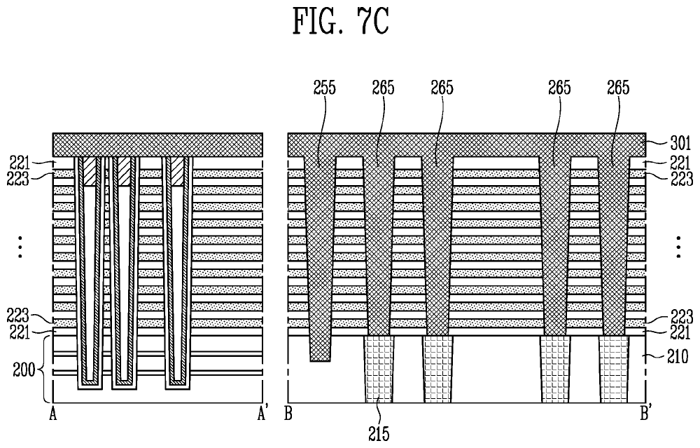

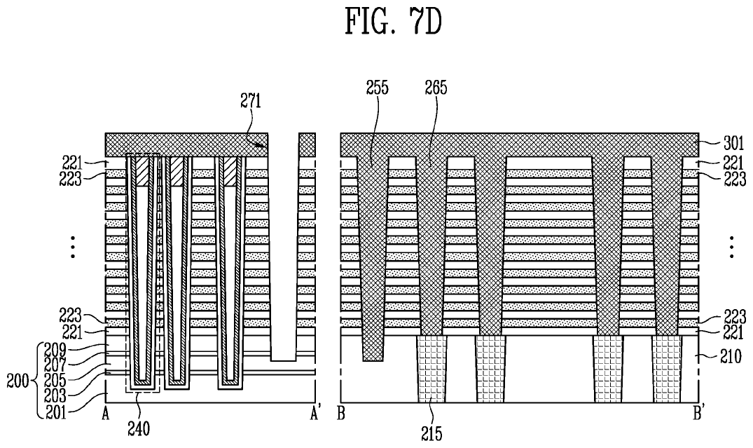

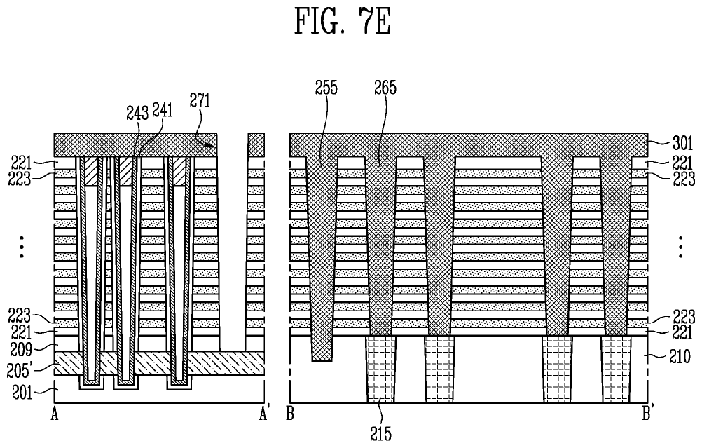

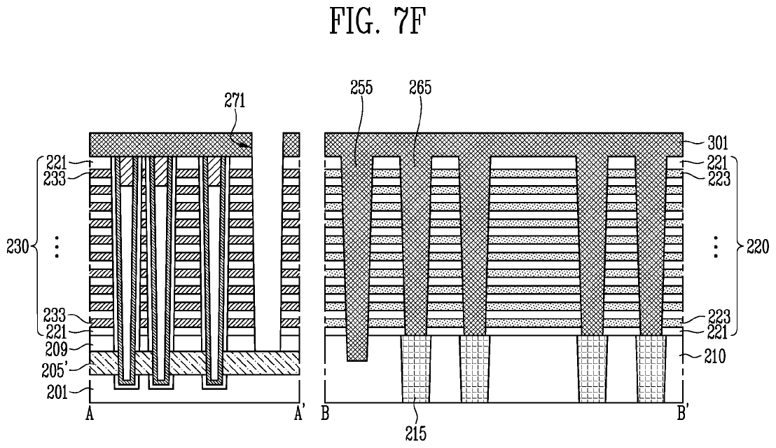

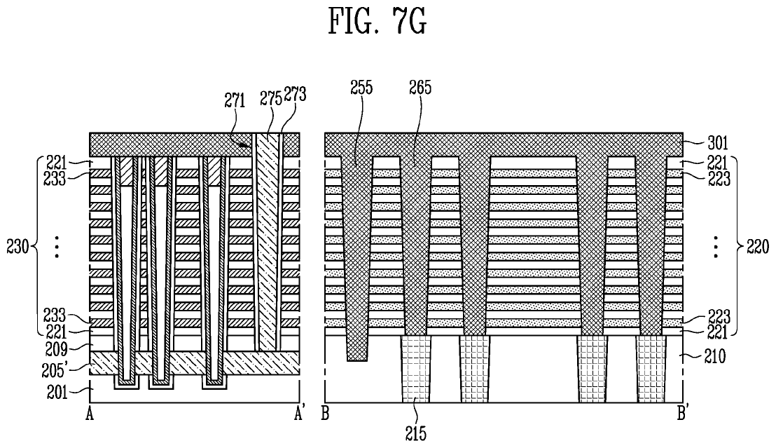

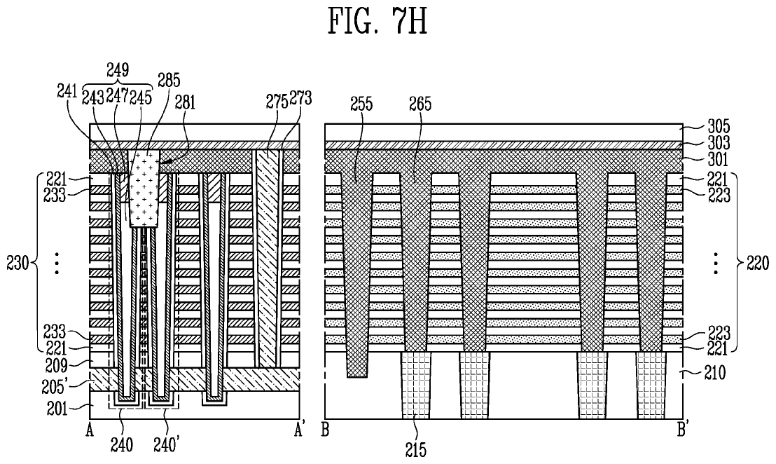

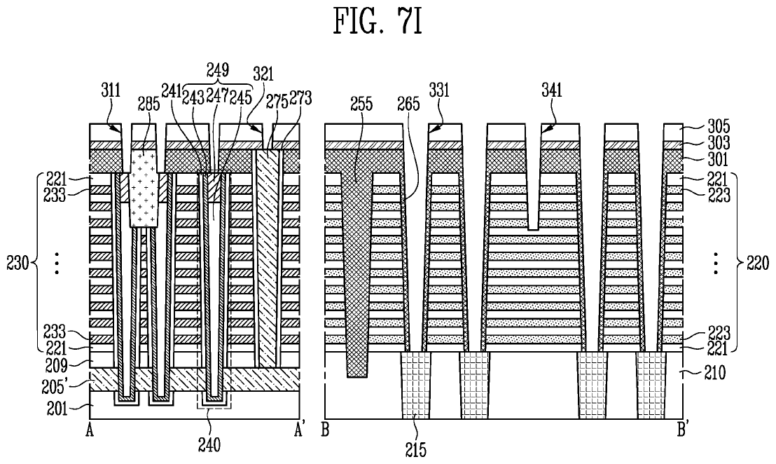

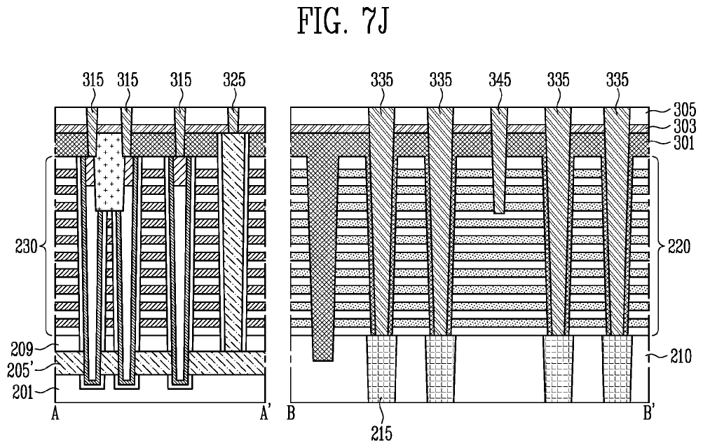

FIGS. 7A to 7J are cross-sectional diagrams taken along line A-A′ and line B-B′ of FIG. 2 for illustrating processes of forming a memory block of a semiconductor memory device.

Referring to FIG. 7A, a preliminary source structure 200 may be formed on the peripheral circuit structure PC as shown in FIG. 6A or the second substrate 101 as shown in FIG. 6B. The preliminary source structure 200 may include a first doped semiconductor layer 201, a first protective layer 203, a sacrificial source layer 205, a second protective layer 207, and an upper semiconductor layer 209.

The first doped semiconductor layer 201 may form the first source layer SL1 as described above with reference to FIG. 3. The first doped semiconductor layer 201 may include a doped silicon layer. The first doped semiconductor layer 201 may include a source dopant. For example, the source dopant may be n type impurities.

The first protective layer 203 and the second protective layer 207 may include a material having different etch rate from the first doped semiconductor layer 201, the sacrificial source layer 205, and the upper semiconductor layer 209. For example, the first protective layer 203 and the second protective layer 207 may include an oxide layer. The sacrificial source layer 205 may include a material having a different etch rate from the first doped semiconductor layer 201 and the upper semiconductor layer 209. For example, the upper semiconductor layer 209 may include undoped silicon.

The upper semiconductor layer 209 may form the third source layer SL3 as described above with reference to FIG. 3. The upper semiconductor layer 209 may include a material having a different etch rate from first material layers 221 and second material layers 223 which are formed during subsequent processes. For example, the upper semiconductor layer 209 may include a doped silicon layer including a source dopant.

A lower insulating layer 210 may be formed at substantially the same height as the preliminary source structure 200. After the preliminary source structure 200 is etched, the lower insulating layer 210 may be arranged in a region from which the preliminary source structure 200 is etched. Subsequently, lower contacts 215 that pass through the lower insulating layer 210 may be formed. The lower contacts 215 may include a conductive material. When the process for forming the memory block is performed on the lower structure of FIG. 6A, the lower contact 215 may be coupled to the peripheral circuit line PLC of the peripheral circuit structure PC as shown in FIG. 6A.

The first material layers 221 and the second material layers 223 may be alternately stacked on the preliminary source structure 200 and the lower insulating layer 210. The first material layers 221 and the second material layers 223 may extend to cover the preliminary source structure 200 and the lower insulating layer 210.

The first material layers 221 may form the interlayer insulating layers ILD and the dummy insulating layers ILD′ as described above with reference to FIG. 3. The second material layers 223 may include a material having a different etch rate from the first material layers 221. According to an embodiment, the first material layers 221 may include silicon oxide, and the second material layers 223 may include silicon nitride. The second material layers 223 may form the sacrificial insulating layers SC as described above with reference to FIG. 3. The first material layers 221 and the second material layers 223 on the lower insulating layer 210 may form the dummy stack STd as described above with reference to FIG. 3.

Subsequently, cell plugs 240 which pass through the first material layers 221 and the second material layers 223 on the preliminary source structure 200 may be formed. The cell plugs 240 may pass through the upper semiconductor layer 209, the second protective layer 207, the sacrificial source layer 205, and the first protective layer 203, and may extend into the first doped semiconductor layer 201. To form the cell plugs 240, after a channel hole is formed through the first material layers 221 and the second material layers 223, a memory layer 241 may be formed on the surface of the channel hole, and a channel layer 243 may be formed on the memory layer 241. Subsequently, a core pillar 245 and a capping pattern 247 may be formed in a central region of the channel hole. The capping pattern 247 may be formed on the core pillar 245. The memory layer 241 may be formed in a liner shape. The channel layer 243 may include a semiconductor layer which serves as a channel region. For example, the channel layer 243 may include silicon. According to an embodiment, the channel layer 243 may be formed in a liner shape, and the central region of the channel hole may include a portion which is not filled with the channel layer 243. The core pillar 245 may include oxide and the capping pattern 247 may include a conductivity type dopant. The conductivity type dopant may include an n type dopant for a junction. The conductivity type dopant may include a counter-doped p type dopant.

Referring to FIG. 7B, a first opening 251 and second openings 261 that pass through the first material layers 221 and the second material layers 223 may be formed. The first opening 251 might not overlap the lower contacts 215 and the second openings 261 may overlap the lower contacts 215. The first opening 251 may pass through a portion of the lower insulating layer 210. The second openings 261 may expose the lower contacts 215.

The first opening 251 and the second opening 261 may have different depths. For example, the first opening 251 may have a greater depth than the second opening 261. The first opening 251 may have the same width as the second openings 261. However, embodiments of the present disclosure are not limited thereto.

Referring to FIG. 7C, a first upper insulating layer 301 that covers the first material layers 221 and the second material layers 223 may be formed. The first opening 251 and the second openings 261 may be filled with the first upper insulating layer 301. A portion of the first upper insulating layer 301 which fills the inside of the first opening 251 may be defined as a support pillar 255. A portion of the first upper insulating layer 301 which fills the second openings 261 may be defined as insulating pillars 265. During the manufacturing process of the semiconductor memory device, the support pillar 255 and the insulating pillars 265 may serve as a support body for preventing warpage of the stacked body of the first material layers 221 and the second material layers 223.

A trench for the vertical barrier VB as shown in FIG. 2 may be formed using the processes of forming the first opening 251 and the second openings 261 as described above with reference to FIG. 7B. While the first upper insulating layer 301 as shown in FIG. 7C is formed, the first upper insulating layer 301 may fill the trench. A portion of the first upper insulating layer 301 which fills the trench may be defined as the vertical barrier VB as shown in FIG. 2.

Referring to FIG. 7D, a first slit 271 which passes through the first upper insulating layer 301, the first material layers 221, and the second material layers 223 may be formed. The first slit 271 may be formed by etching the first material layers 221, the second material layers 223, the upper semiconductor layer 209, and the second protective layer 207 to expose the sacrificial source layer 205. According to an embodiment, a lowermost portion of the first slit 271 may be arranged in the sacrificial source layer 205. The sacrificial source layer 205 may serve as an etch stop layer when the first slit 271 is formed.

Referring to FIG. 7E, the sacrificial source layer 205 which is exposed through the first slit 271 may be removed. A material by which the sacrificial source layer 205 is etched through the first slit 271 may be injected to remove the sacrificial source layer 205. While the sacrificial source layer 205 is removed, the first protective layer 203 and the second protective layer 207 may protect the first doped semiconductor layer 201 and the upper semiconductor layer 209, respectively. According to an embodiment, while the sacrificial source layer 205 is removed, the first protective layer 203 and the second protective layer 207 might not be etched.

By etching a portion of the memory layer 241 exposed through the region from which the sacrificial source layer 205 is removed, a sidewall of the channel layer 243 may be exposed. While the portion of the memory layer 241 is removed, the first protective layer 203 and the second protective layer 207 may be removed. As a result, the first doped semiconductor layer 201 and the upper semiconductor layer 209 may be exposed.

A region from which the sacrificial source layer 205 and the portion of the memory layer 241 are removed may be filled with a second doped semiconductor layer 205′, According to an embodiment, the second doped semiconductor layer 205′ may include polysilicon. The second doped semiconductor layer 205′ may be doped with at least one of n type impurities and p type impurities. The second doped semiconductor layer 205′ may contact the sidewall of the channel layer 243, the first doped semiconductor layer 201, and the upper semiconductor layer 209. The first doped semiconductor layer 201, the second doped semiconductor layer 205′, the upper semiconductor layer 209 may form the source structure SL as shown in FIG. 3.

Referring to FIG. 7F, after the second material layers 223 which surround the cell plugs 240 are removed through the first slit 271, the regions from which the second material layers 223 are removed may be filled with third material layers. Each of the third material layers 233 may include at least one of a doped silicon layer, a metal silicide layer, and a metal layer. Each of the third material layers 233 may include a low-resistance metal such as tungsten for low-resistance wiring. Each of the third material layers 233 may further include a barrier layer such as titanium nitride layer, a tungsten nitride layer, or a tantalum nitride layer.

The first material layers 221 and the third material layers 233 on the upper semiconductor layer 209 may be defined as a cell stack 230. The first material layers 221 and the second material layers 223 on the lower insulating layer 210 may be defined as a dummy stack 220.

Referring to FIG. 7G, a spacer insulating layer 273 may be formed on the sidewall of the first slit 271 so as to cover sidewalls of the third material layers 233.

Subsequently, the first slit 271 may be filled with a source contact structure 275. The source contact structure 275 may be formed on a spacer insulating layer 253 and contact the second doped semiconductor layer 205′. The source contact structure 275 may include a conductive material. However, embodiments of the present disclosure are not limited thereto. According to an embodiment, the source contact structure 275 may be omitted and the first slit 271 may be filled with an insulating material.

Referring to FIG. 7H, a drain select line isolation structure 285 may be formed. The drain select line isolation structure 285 may be deep enough to pass through at least one third material layer among the third material layers 233 including the conductive material. The third material layer which is penetrated by the drain select line isolation structure 285 may be separated into drain select lines. The drain select line isolation structure 285 may include an insulating material. The drain select line isolation structure 285 may extend into the cell plug 240 adjacent thereto among the cell plugs 240.

The cell plug 240 may include a channel structure 249 and the memory layer 241 which surrounds the channel structure 249. The channel structure 249 may include the channel layer 243, the core pillar 245, and the capping pattern 247. The core pillar 245 and the capping pattern 247 may fill a central region of the channel structure 249.

Subsequently, a second upper insulating layer 303 and a third upper insulating layer 305 may be formed to cover the first upper insulating layer 301. The second upper insulating layer 303 may include a material having an etch selectivity with respect to the first upper insulating layer 301 and the third upper insulating layer 305. According to an embodiment, the first upper insulating layer 301 and the third upper insulating layer 305 may include oxide, and the second upper insulating layer 303 may include nitride.

Referring to FIG. 7I, first upper holes 311 and second upper holes 321 may be formed through at least one of the first, second, and third upper insulating layers 301, 303, and 305 on the cell stack 230. The first upper holes 311 may expose the capping pattern 247 of the cell plug 240. The second upper hole 321 may expose the source contact structure 275.

When the first upper holes 311 and the second upper hole 321 are formed, contact plug holes 331 and a dummy contact hole 341 may be formed through the dummy stack 220 and the first, second, and third upper insulating layers 301, 303, and 305 on the dummy stack 220. The contact plug holes 331 may pass through the insulating pillar 265 in the second opening 261 as described above with reference to FIG. 7B. The dummy contact hole 341 may be arranged in a region where the density of the contact plug holes 331 varies drastically. Therefore, the contact plug holes 331 adjacent to the region where the density is drastically changed due to etch loading which occurs during the etch processes for forming the dummy contact hole 341 and the contact plug holes 331 may be prevented from being formed at a low depth. Accordingly, non-exposure of some of the lower contacts 215 caused by etch loading may be avoided, so that non-contact between the lower contacts 215 and a contact plug 335 to be described below with reference to FIG. 73 may be prevented or mitigated. As a result, according to an embodiment, the operational reliability of the semiconductor memory device may be improved.

The dummy contact hole 341 may have a smaller width than the contact plug holes 331. The dummy contact hole 341 which has a relatively small width may have a lower depth than the contact plug holes 331 which have a relatively large width. Therefore, the dummy contact hole 341 might not completely pass through the dummy stack 220. In other words, the dummy contact hole 341 may pass through a portion of the dummy stack 220.

Referring to FIG. 7J, first upper contacts 315 and a second upper contact 325 may be formed by filling the first upper holes 311 and the upper hole 321 as described above with reference to FIG. 7I with a conductive material. In addition, by filling the contact plug holes 331 and the dummy contact hole 341 with a conductive material, contact plugs 335 and a dummy contact 345 may be formed.

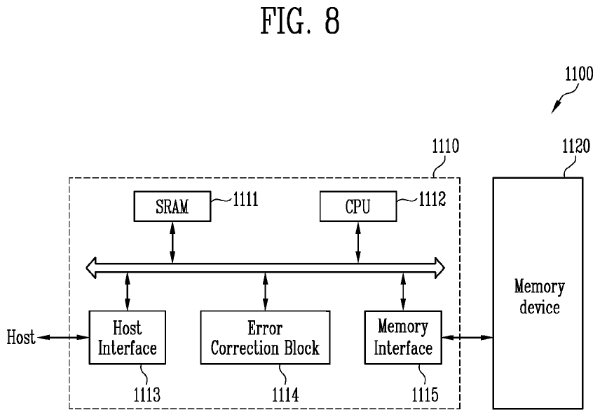

FIG. 8 is a block diagram illustrating a configuration of a memory system 1100 according to an embodiment of the present disclosure.

Referring to FIG. 8, the memory system 1100 includes a memory device 1120 and a memory controller 1110.

The memory device 1120 may be a multichip package which includes a plurality of flash memory chips.

The memory controller 1110 may be configured to control the memory device 1120, and may include static random access memory (SRAM) 1111, a central processing unit (CPU) 1112, a host interface 1113, an error correction block 1114, and a memory interface 1115. The SRAM 1111 may serve as operation memory of the CPU 1112, the CPU 1112 may perform an overall control operation for data exchange of the memory controller 1110, and the host interface 1113 may include a data exchange protocol of a host connected to the memory system 1100. In addition, the error correction block 1114 may detect and correct an error included in data read from the memory device 1120, and the memory interface 1115 may perform interfacing with the memory device 1120. In addition, the memory controller 1110 may further include read only memory (ROM) that stores code data for interfacing with the host.

The memory system 1100 may be a memory card or a solid state drive (SSD) into which the memory device 1120 and the memory controller 1110 are integrated. For example, when the memory system 1100 serves as the SSD, the memory controller 1110 may communicate with an external device (e.g., a host) through one of the interface protocols including Universal Serial Bus (USB), MultiMedia Card (MMC), Peripheral Component Interconnection-Express (PCI-E), Serial Advanced Technology Attachment (SATA), Parallel Advanced Technology Attachment (DATA), Small Computer System Interface (SCSI), Enhanced Small Disk Interface (ESDI), and Integrated Drive Electronics (IDE).

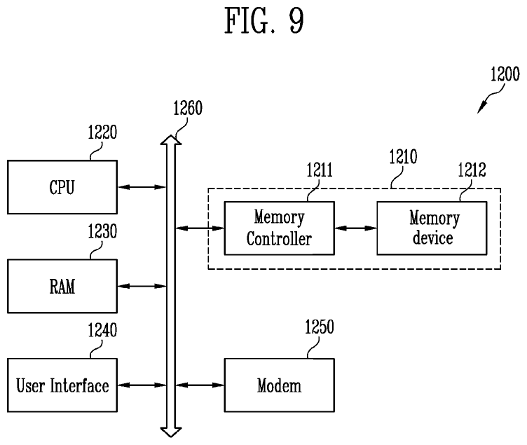

FIG. 9 is a block diagram illustrating a configuration of a computing system 1200 according to an embodiment of the present disclosure.

Referring to FIG. 9, the computing system 1200 may include a CPU 1220, random access memory (RAM) 1230, a user interface 1240, a modem 1250, and a memory system 1210 which are electrically connected to a system bus 1260. In addition, when the computing system 1200 is a mobile device, a battery for supplying an operating voltage to the computing system 1200 may be further included. In addition, an application chipset, an image processor, a mobile DRAM, and the like may be further included.

The memory system 1210 may include a memory device 1212 and a memory controller 1211.

The memory controller 1211 may be configured in the same manner as the memory controller 1110 as described above with reference to FIG. 8.

According to various embodiments, operational reliability may be improved by preventing or mitigating a structural defect by forming a dummy contact arranged between a plurality of plugs to pass through a portion of a stacked structure (i.e., dummy stack STd).

It will be apparent to those skilled in the art that various modifications can be made to the above-described embodiments of the present disclosure without departing from the spirit or scope of the disclosure. Thus, it is intended that the present disclosure cover all such modifications provided they come within the scope of the appended claims and their equivalents.

What is claimed is:

1. A semiconductor memory device, comprising:
a second lower insulating layer;
a dummy stack on the second lower insulating layer;
a source structure arranged at substantially a same level as the second lower insulating layer;
a cell stack on the source structure;
a plurality of contact plugs passing through the dummy stack; and
a dummy contact passing through a portion of the dummy stack and arranged between the contact plugs,
wherein each of the dummy and cell stack structures includes a plurality of first material layers separated from each other, the first material layers stacked on top of each other,
wherein the dummy stack further includes a plurality of second material layers arranged alternately with the plurality of first material layers on the second lower insulating layer, and
wherein the cell stack further includes a plurality of third material layers arranged alternately with the plurality of first material layers on the source structure.

2. The semiconductor memory device of claim 1, further comprising a plurality of cell plugs passing through the cell stack,
wherein the cell plugs include a channel layer and a memory layer surrounding a sidewall of the channel layer.

3. The semiconductor memory device of claim 2, wherein the source structure includes a first source layer and a second source layer, the second source layer arranged on the first source layer.

4. The semiconductor memory device of claim 2, wherein the channel layer of each of the cell plugs is directly coupled to the source structure.

5. The semiconductor memory device of claim 1, wherein a height of the dummy contact is smaller than a height of each of the contact plugs.

6. The semiconductor memory device of claim 1, wherein the plurality of contact plugs include first to third contact plugs arranged in a line,
wherein the second contact plug is arranged between the first contact plug and the third contact plug, and
wherein a distance between the first contact plug and the second contact plug is greater than a distance between the second contact plug and the third contact plug.

7. The semiconductor memory device of claim 6, wherein the dummy contact is arranged between the second contact plug and the third contact plug.

8. The semiconductor memory device of claim 1, further comprising:
a vertical barrier arranged between the dummy stack and the cell stack; and
a support pillar passing through the dummy stack.

9. The semiconductor memory device of claim 1, wherein a width of a top surface of the contact plug is greater than a width of a top surface of the dummy contact.

10. A semiconductor memory device, comprising:
a substrate on which a cell array region and a connection region are defined;
a peripheral circuit structure on the substrate;
a dummy stack arranged on the connection region;
a cell stack arranged on the cell array region;
a plurality of contact plugs passing through the dummy stack;
cell plugs passing through the cell stack; and
a dummy contact passing through a portion of the dummy stack.

11. The semiconductor memory device of claim 10, wherein the dummy stack includes dummy insulating layers and sacrificial insulating layers stacked alternately with each other, and
wherein the cell stack includes interlayer insulating layers and conductive patterns stacked alternately with each other.

12. The semiconductor memory device of claim 10, further comprising a plurality of lower contacts coupling the peripheral circuit structure to the plurality of contact plugs.

13. The semiconductor memory device of claim 10, further comprising:
a first upper insulating layer arranged on the dummy stack and the cell stack; and
a support pillar passing through the dummy stack, wherein the first upper insulating layer and the support pillar include a same material.

14. The semiconductor memory device of claim 10, further comprising a vertical barrier surrounding the dummy stack.

15. The semiconductor memory device of claim 10, wherein each of the cell plugs includes a channel structure and a memory layer surrounding the channel structure, and
wherein the memory layer includes a tunnel isolation layer, a data storage layer, and a blocking insulating layer stacked sequentially on a surface of the channel structure.

16. The semiconductor a memory device of claim 10, wherein a top width of each of the contact plugs is greater than a top width of the dummy contact.

17. The semiconductor memory device of claim 10, wherein the dummy contact having a smaller length than each of the contact plugs is arranged in the dummy stack.

18. The semiconductor memory device of claim 10,
wherein the plurality of contact plugs include first to third contact plugs passing through the dummy stack and arranged in a line,
wherein the second contact plug is arranged between the first contact plug and the third contact plug, and
wherein a distance between the first contact plug and the second contact plug is greater than a distance between the second contact plug and the third contact plug.

19. The semiconductor memory device of claim 18, wherein the dummy contact is arranged between the second contact plug and the third contact plug.
